(19) United States
(12) Patent Application Publication
(10) Pub. No.: US 2003/0160150 A1
(43) Pub. Date: Aug. 28, 2003

(54) Image sensor assembly and a carriage using the same

(76) Inventor: Thomas Sheng, Hsin Chu (TW)

Correspondence Address: CHARLES E. BAXLEY, ESQUIRE, Hart, Baxley, Daniels & Holton, 59 John St, 5 Fl, New York, NY, 10038, US

(21) Appl. No.: 10/233,820

(22) Filed: Sep. 3, 2002

(30) Foreign Application Priority Data
Feb. 22, 2002 (TW) 091103122

(51) Int. Cl. H01L 27/00

(52) U.S. Cl. 250/208.1

(57) ABSTRACT

An image sensor assembly includes a sensor base and plural image sensors. Each image sensor includes plural sensor pixels. The plural sensor pixels and the plural image sensors are arranged in the same direction. Each image sensor is fixed on the sensor base, and each image sensor corresponds to a next one so that all image sensors can be aligned. There is a predetermined gap between two adjacent image sensors. Therefore, each image sensor is not skew and shifted when the image sensor assembly is mounted on the carriage, and the skew problem between each image sensor and the carriage base can be solved by micro-adjusting the position of the sensor base relative to the carriage base.

### FIELD OF THE INVENTION

The present invention relates to an image sensor assembly and a carriage using the image sensor assembly, and more particularly to an image sensor assembly with multiple aligned image sensors and a carriage using the image sensor assembly.

### BACKGROUND OF THE INVENTION

In the application for a conventional scanner with a normal size, it is possible to use multiple image sensors to receive images so as to reduce the total path of light of each of the carriages. In the application of a large-format scanner, multiple image sensors are typically used to receive images. Due to the fact that fragments of the document are received respectively or individually by the sensors, the images of the fragments have to be stitched by image connecting techniques. If there are some errors between the multiple sensors, the stitching of the images has to be treated by complicated post-image techniques and calculations.

Conventionally, each image sensor is mounted on a circuit board and multiple circuit boards are installed to the carriage. The positioning error of each sensor on the circuit board and the positioning error of each circuit board on the carriage result in skew problems between the sensors. The skew problem will cost much more time for the complicated calculation.

The skew problem can be solved by adjusting the position of each of the circuit boards. However, the image being sensed between the adjacent circuits could still be skew even if the sensors on the circuit boards are aligned to the carriage. The adjustment consumes a lot of time and labor.

A reasonable conclusion is to replace the multiple image sensors with one large-format image sensor, and this way is able to resolve the skew problem between the image sensors. Nevertheless, it is four times as much as the present price of the image sensor when only two times of pixels are increased, which is not proportional. Therefore, it costs too much to use large-format image sensors.

In practical use, the image sensor sends the electronic signal in sequence so that it takes a long period of time to send all the electronic signals and the scanning period is increased. This is a shortcoming of design for the large-format scanner.

### SUMMARY OF THE INVENTION

The present invention uses multiple image sensors precisely connected to a sensor base which is adjustably connected to a carriage. By this way, the skew problem between the image sensors can be solved and the shift problem of the image sensor relative to the carriage can also be solved.

The primary object of the present invention is to provide image sensors and a carriage that uses the image sensors, which reduces the mechanical errors and makes the image sensors be located at correct positions without skew.

Another object of the present invention is to provide image sensors and a carriage using the image sensors, wherein the skew problem between the sensors and the carriage can be solved simultaneously.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show the present invention.

FIG. 2 shows a plane view of the sensor base of the present invention.

FIG. 3 shows the assembly of the sensor base and the carriage base.

FIG. 4 shows the image obtained by the present invention.

### DETAILED DESCRIPTION OF THE PREFERRED EMBODIMENT

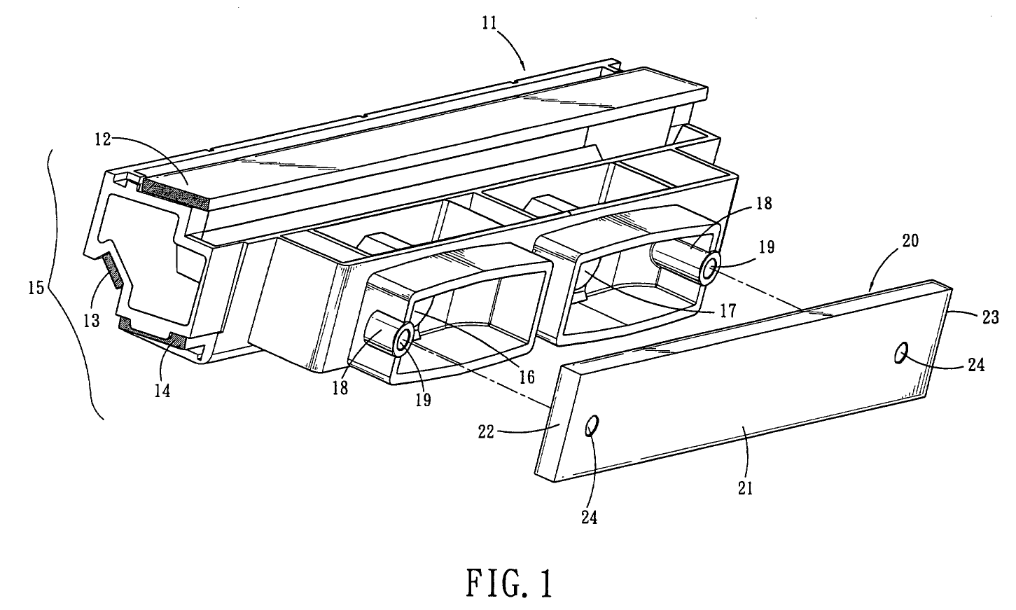

FIG. 1 shows an exploded view of the carriage of the present invention. The carriage comprises a carriage base 11 and an image sensor assembly 20. The image sensor assembly 20 includes a sensor base 21. A plurality of reflection mirrors 12, 13, 14 are fixed to the carriage base 11 and are named as a reflection mirror unit 15. At least two lenses 16, 17 are installed on the carriage base 11 and located at the remote end of the reflection mirror unit 15.

The image sensor assembly 20 is mounted on the carriage base 11 and located away from the reflection mirror unit 15 and correspondingly to the two lenses 16, 17 so as to receive image information.

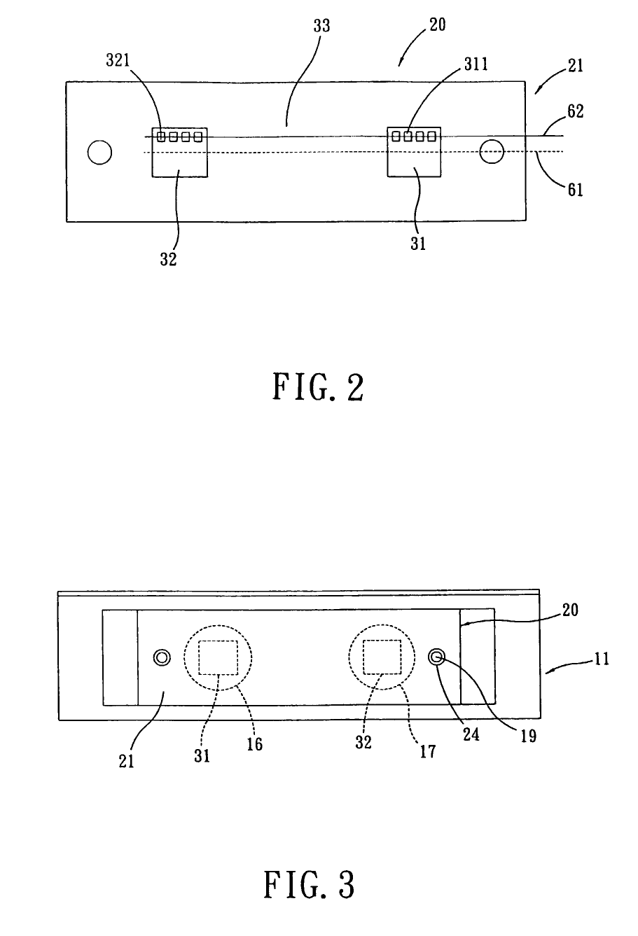

FIG. 2 shows the plane view of the image sensor assembly 20 and the sensor base 21 of the image sensor assembly 20 is located corresponding to the surface of the reflection mirror (not shown). The image sensor assembly 20 includes two image sensors 31, 32 that are fixedly located and aligned in a first line 61. The image sensors 31, 32 can be CCD type, CMOS type or any other types. The image sensor 31 includes plural sensor pixels 311 and the image sensor 32 includes plural sensor pixels 321. The sensor pixels 311 are located and aligned in a second line 62. The two lines 61, 62 have the same direction and preferably, the first line 61 and the second line are overlapped.

It is to be noted that, when proceeding color scanning, the image sensor 32 may include the sensor pixels 321 which are arranged into multiple parallel lines. In this invention, this is deemed as the sensor pixels 321 arranged in multiple second lines. Similarly, the image sensor 31 is the same as the image sensor 32 and will not be described in detail.

Furthermore, in the design of the optional embodiments, the second line of the sensor pixels 311, 321 may have a gap defined therebetween. Anyway, the direction (the second direction) of arrangement of the sensor pixels is the same as the direction (the first direction) of the arrangement of the image sensors.

It is to be noted that the two image sensors 31, 32 can be installed on the sensor base 21 by way of the packing method for semi-conductors. A pre-determined gap 33 is defined between the two image sensors 31, 32 which are not connected with each other snugly. The size of the gap 33 depends on the total track of the carriage, the features of the lenses, and the overlapping of the images sensed by the two sensors.

By the precise packing skill of the semi-conductors, the two or more than two image sensors 31, 32 can be precisely positioned. The precise positioning mentioned above means the X axle and the Y axle (as shown in the figure) of the two image sensors 31, 32 have no skew or shift. It can be well done for the packing technique.

Referring to FIG. 1 again, the carriage base 11 has two locking portions 18 and a threaded hole 19 is defined axially therein. Locking holes 24 are defined in the sensor base 21 near the two ends 22, 23 of the sensor base 21. The inner diameter of the threaded hole 24 may be larger than that of the threaded holes 19 and smaller than the outer diameter of the locking portions 18.

FIG. 3 shows the assembly of the sensor assembly 20 and the carriage base 11, wherein the side having the image sensors 31, 32 of the sensor base 21 faces the lenses 16, 17, and the locking holes 24 face the threaded holes 19. Proper locking members such as screws (not shown) are engaged with the locking holes 24 and the threaded holes 19 to fix the sensor base 21 to the carriage base 11. The image sensors 31, 32 face the lenses 16, 17.

It is to be noted that after the sensor base 21 is fixed to the carriage base 11, the positioning of the image sensors 31, 32 has to be examined by equipment so as to ensure that no skew is found to the image sensors 31, 32. Once the image sensors 31, 32 are skew in positioning, the sensor assembly 20 has to be adjusted to make the image sensors 31, 32 not to be skew relative to the carriage base 11.

Because the adjustment for the sensor assembly 20 is minor and the inner diameter of the threaded hole 24 is larger than that of the threaded holes 19, after the adjustment of the sensor assembly 20 and the carriage base 11, the locking members are not affected.

Regarding the position adjustment of the sensor assembly 20, besides that the inner diameter of the threaded hole 24 is larger than that of the threaded holes 19, the locking holes 24 can be elongated.

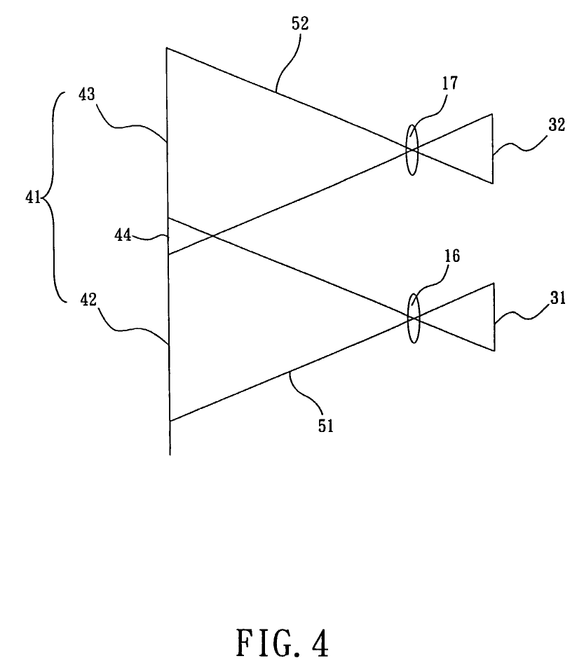

FIG. 4 shows the image obtained by the present invention. When scanning the document 41, the image information 51 of a part 42 of the document 41 passes through the lens 16 and is received by the image sensor 31. The image information 52 of another part 43 of the document 41 passes through the lens 17 and is received by the image sensor 32.

When obtaining the image, the image sensors 31, 32 receive the overlap portion 44 of the two parts 42, 43 and the overlap portion 44 can be treated by soft-ware calculation and does not affect the final output result of the image.

Because the image sensors 31, 32 are precisely positioned on the sensor base 21, there will be no skew and shift on the two adjacent image sensors 31, 32. The error of positioning between the image sensors 31, 32 are overcome. The corresponding relationship between the multiple sensors 31, 32 and the multiple lenses 16, 17 can be adjusted while adjusting the sensor base 21. It is simple and easy to adjust the sensors 31, 32 and no skew and shift problems will be raised.

Therefore, the present invention reduces the mechanical errors for the assembling of the image sensors 31, 32 and the carriage and the time required for post processing the image is also shortened. By using the image sensor assembly 20, the total track, the cost of the lenses, and the cost for assembling the carriage are reduced.

Besides, for the adjustment and assembling of the image sensors 31, 32 of a large carriage, the mechanical error is reduced and the time required to post processing the image is shortened.

While we have shown and described the embodiment in accordance with the present invention, it should be clear to those skilled in the art that further embodiments may be made without departing from the scope of the present invention.

What is claimed is:

1. An image sensor assembly comprising:
a sensor base, and
plural image sensors arranged in a first direction, each image sensor having plural sensor pixels arranged in a second direction, the first direction and the second direction being the same, the image sensors being fixed to the sensor base and correspondingly aligned, and a predetermined gap being defined between two adjacent image sensors.

2. The assembly as claimed in claim 1, wherein the plural image sensors are fixedly packaged on the sensor base.

3. A carriage comprising:
a carriage base;
a reflection mirror unit arranged on the carriage base;
multiple lenses away from the reflection mirror unit and arranged on the carriage base;
a sensor base adjustably mounted on the carriage base and having a surface facing the multiple lenses; and
plural image sensors arranged in a line and fixed to the surface of the sensor base facing the lenses, the image sensors being correspondingly aligned, and a predetermined gap being defined between two adjacent image sensors so that each image sensor is located corresponding to the lenses.

4. The carriage as claimed in claim 3, wherein the plural image sensors are fixedly packaged on the sensor base.

5. The carriage as claimed in claim 3, wherein each image sensor includes plural sensor pixels arranged in a direction which is the same as a direction of the arrangement of the image sensors.
